(19) United States
(12) Patent Application Publication
(10) Pub. No.: US 2007/0236251 A1
(43) Pub. Date: Oct. 11, 2007

(54) LEVEL-SHIFTING APPARATUS AND PANEL DISPLAY APPARATUS USING THE SAME

(76) Inventor: Cheng-Wen Chang, Hsinchu City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, omitted

(21) Appl. No.: 11/309,144

(22) Filed: Jun. 27, 2006

(30) Foreign Application Priority Data
Mar. 30, 2006 (TW) 95111133

(51) Int. Cl. H03K 19/0175

(52) U.S. Cl. 326/68

(57) ABSTRACT

A level-shifting apparatus and a panel display apparatus using the same are disclosed. The level-shifting apparatus is used for receiving and changing the level of an input signal to generate an output signal. The level-shifting apparatus includes a first unit and a second unit. The first unit is for deciding whether a first switching signal and a second switching signal are to be output according to the input signal and the output signal. The second unit generates the output signal according to the first switching signal and the second switching signal. Wherein, the input signal is operated between a first level and a second level, while the output signal is operated between a third level and a fourth level.

### CROSS-REFERENCE TO RELATED APPLICATION

This application claims the priority benefit of Taiwan application serial no. 95111133, filed on Mar. 30, 2006. All disclosure of the Taiwan application is incorporated herein by reference.

### BACKGROUND OF THE INVENTION

1. Field of Invention

The present invention relates to a level-shifting apparatus, and more particularly, to a level-shifting apparatus capable of simultaneously converting the original first level and second level into a third level and a fourth level and to a panel display apparatus using the level-shifting apparatus.

2. Description of the Related Art

The level-shifting apparatus is an indispensable interface circuit between circuits with different operation voltages. For example, the level-shifting apparatus is one of the important components of the thin film transistor liquid crystal display (TFT LCD), wherein the level-shifting apparatus serves for providing gate signals to switch pixels. In a TFT LCD, a pixel is normally switched by a gate signal with a certain level adjusted by a level-shifting apparatus cooperating with a source signal level.

Referring to FIG. 1, the configuration and the principle of a conventional level-shifting apparatus can be explained herein. A conventional level-shifting apparatus in FIG. 1 employs a level shifter 101 and a level shifter 102 in combination and converts an input signal Sᵢₙ₁ (as shown by the arrow of dotted line 110) with a voltage level between a first level V_{DD} and a second level V_{SS} into two output signals Sₒᵤₜ₁ and S_{outb1} with a voltage level between a third level AV_{DD} and a fourth level V_{CL} (as shown by the arrow 130). The level relationships among the first level, the second level, the third level and the fourth level are: the third level AV_{DD}>the first level V_{DD}>the second level V_{SS}>the fourth level V_{CL}. To implement the level conversion in the real operation, at a point of timing, an inverter 103 is used to turn on one of N-type transistors MN11 and MN12 in the level shifter 101. Thus, one of P-type transistors MP11 and MP12 in the level shifter 101, i.e. the P-type transistor where the gate terminal thereof is connected to the turned-on N-type transistor, would be turned on as the voltage at the gate terminal thereof is pulled to the second level V_{SS}. At the point, the level shifter 101 is able to generate signals S₁₁ and S₁₂ between the third level AV_{DD} and the second level V_{SS} (as shown by the arrow 120). Afterwards, the output signals S₁₁ and S₁₂ of the level shifter 101 serve as the input signals of the level shifter 102. Taking an approach similar to the level shifter 101, the level shifter 102 is able to generate signals Sₒᵤₜ₁ and S_{outb1} between the third level AV_{DD} and the fourth level V_{CL} (as shown by the arrow 130).

From the above described, it can be seen that the conventional level-shifting apparatus is formed by connecting in series two level shifters 101 and 102. Such an implementation scheme to change the level of input signal Sᵢₙ₁ in separated divisions can be summarized as follows: converting the first level V_{DD} into the third level AV_{DD} by using the first level shifter, and then converting the second level V_{SS} into the fourth level V_{CL} by using the second level shifter. Since quite a number of transistors are employed in the prior art, therefore, the cost of an LCD adopting the conventional technology would be significantly increased.

### SUMMARY OF THE INVENTION

An objective of the present invention is to provide a level-shifting apparatus. In comparison with the conventional configuration, the level-shifting apparatus has a reduced transistor number, which results in a smaller chip size.

Another objective of the present invention is to provide a panel display apparatus, which employs the level-shifting apparatus with a less transistor number to downsize the circuit layout area and further to lower the cost.

To achieve the above-described or other objectives, the present invention provides a level shifter apparatus, which includes a first unit and a second unit. The first unit decides whether a first switching signal and a second switching signal are to be output according to the input signal received by the level-shifting apparatus and the output signal generated by the second unit. Afterwards, the second unit generates an output signal according to the first switching signal and the second switching signal. Wherein, the input signal is operated between the first level and the second level, the output signal is operated between the third level and the fourth level, the first switching signal is operated between the third level and the second level and the second switching signal is operated between the first level and the fourth level.

According to the embodiment of the present invention, in the level-shifting apparatus, the level relationships among the first level, the second level, the third level and the fourth level are: the third level>the first level>the second level>the fourth level. The first unit of the embodiment includes a first switch, a second switch, a first switching unit and a second switching unit; the second unit includes a ninth switch and a tenth switch. The first switching unit decides whether the first switching signal is to be output according to the input signal and the on/off status of the first switch. The second switching unit decides whether the second switching signal is to be output according to the input signal and the on/off status of the second switch. When the input signal takes the first level, the first switching unit outputs the first switching signal with the second level and the second switching unit does not generate any signal. At the point, the ninth switch is turned on according to the first switching signal and an output signal with the third level is generated. Further, the second switch is turned on according to the output signal fed back to the first unit, which makes the second switching unit generate the second switching signal with the fourth level. On the other hand, when the input signal takes the second level, the second switching unit outputs the second switching signal with the first level and the first switching unit does not generate any signal. At the point, the tenth switch is turned on according to the second switching signal and an output signal with the fourth level is generated. Further, the first switch is turned on according to the output signal fed back to the first unit, which makes the first switching unit generate the first switching signal with the third level.

The present invention further provides a panel display apparatus, which includes a display panel, a source driving circuit, a gate driving circuit and a level-shifting apparatus. The source driving circuit outputs a source signal for driving the display panel. The gate driving circuit outputs a gate signal cooperating with the timing of the source driving circuit. The level-shifting apparatus is connected in series between the display panel and the gate driving circuit for receiving and changing the level of a first gate signal, followed by generating a second gate signal. The level-shifting apparatus includes a first unit and a second unit. The first unit decides whether a first switching signal and a second switching signal are to be output according to the first gate signal and the second gate signal. The second unit generates the second gate signal according to the first switching signal and the second switching signal. In addition, the first gate signal is operated between a first level and a second level, the second first gate signal is operated between a third level and a fourth level, the first switching signal is operated between the third level and the second level and the second switching signal is operated between the first level and the fourth level.

According to the panel display apparatus provided by an embodiment of the present invention, the level relationships among the first level, the second level, the third level and the fourth level are: the third level>the first level>the second level>the fourth level.

In comparison with the conventional configuration, the level-shifting apparatus of the present invention takes a different scheme from the conventional apparatus where two stages of level shifters are used to change the level of an input signal in separated divisions (first, the first stage of level shifters is used to shift the high-voltage level of the input signal to a higher level, and then the second stage of level shifters is used to shift the low-voltage level of the input signal to a lower level). In the present invention, a single-stage level-shifting apparatus is used to directly change the level of an input signal, that is to say, both the high-voltage level and low-voltage level of the input signal are simultaneously converted into a higher level and a lower level, respectively. Such a scheme by using a less transistor number leads to a downsized circuit layout area. Besides, when a panel display apparatus of mass production employs the level-shifting apparatus of the present invention, the cost of the panel display apparatus would be largely reduced.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve for explaining the principles of the invention.

FIG. 1 is a circuit drawing of a conventional level-shifting apparatus.

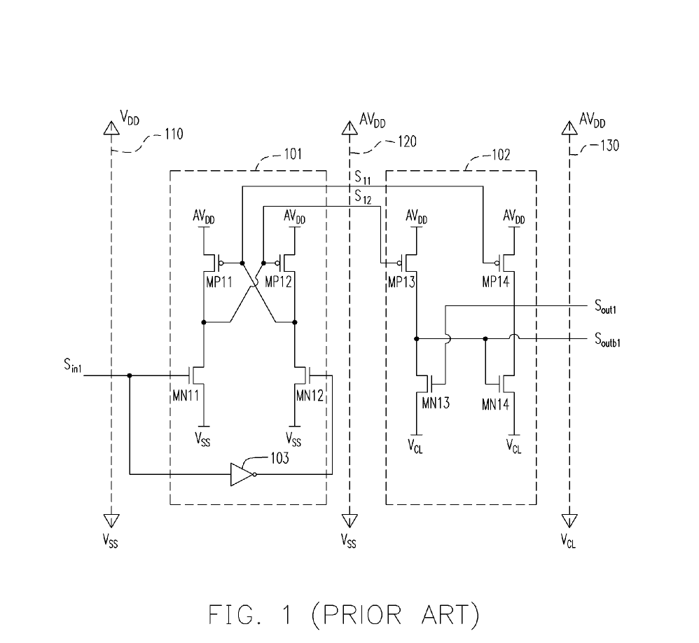

FIG. 2 is a block diagram of a level-shifting apparatus according to an embodiment of the present invention.

FIG. 3 is a circuit configuration drawing of a level-shifting apparatus according to an embodiment of the present invention.

FIG. 4 is a circuit drawing of a level-shifting apparatus according to an embodiment of the present invention.

FIG. 5 is a circuit drawing of a level-shifting apparatus according to another embodiment of the present invention.

FIG. 6 is a block diagram of a panel display apparatus according to an embodiment of the present invention.

### DESCRIPTION OF THE EMBODIMENTS

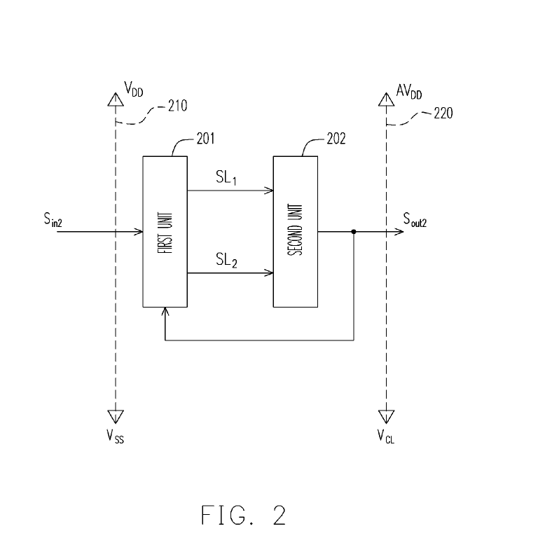

FIG. 2 is a block diagram of a level-shifting apparatus according to an embodiment of the present invention. Referring to FIG. 2, the level-shifting apparatus includes a first unit 201 and a second unit 202. The first unit 201 is electrically connected to the second unit 202 to decide whether a switching signal SL₁ and a switching signal SL₂ are to be output according to an input signal Sᵢₙ₂ and an output signal Sₒᵤₜ₂. Afterwards, the second unit 202 generates the output signal Sₒᵤₜ₂ according to the switching signals SL₁ and SL₂. Wherein, the input signal Sᵢₙ₂ is operated between a first level V_{DD} and a second level V_{SS} (as shown by the arrow 210), the output signal Sₒᵤₜ₂ is operated between a third level AV_{DD} and a fourth level V_{CL} (as shown by the arrow 220), the first switching signal SL₁ is operated between the third level AV_{DD} and the second level V_{SS} and the second switching signal SL₂ is operated between the first level V_{DD} and the fourth level V_{CL}. In the embodiment, the level relationships among the first level, the second level, the third level and the fourth level are: the third level AV_{DD}>the first level V_{DD}>the second level V_{SS}>the fourth level V_{CL}.

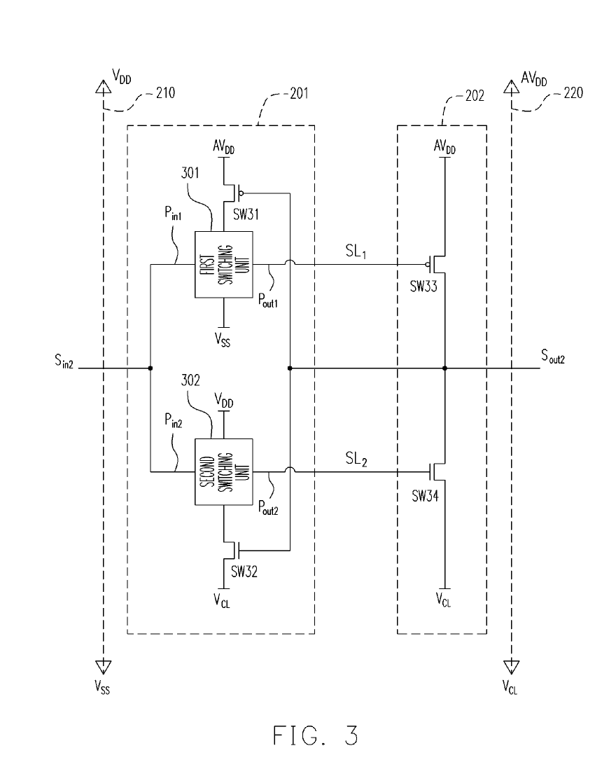

FIG. 3 is a circuit configuration drawing of the embodiment in FIG. 2. As shown in FIG. 3, a first unit 201 includes switches SW31 and SW32, a first switching unit 301 and a second switching unit 302. A second unit 202 includes switches SW33 and SW34. In the present embodiment, the switches SW31 and SW33 are respectively formed by a P-type transistor, while the switches SW32 and SW34 are respectively formed by an N-type transistor. The first terminal of the switch SW31 is electrically connected to a third level AV_{DD}. The first switching unit 301 is electrically connected between the second terminal of the switch SW31 and a second level V_{SS} and has an input terminal Pᵢₙ₁ and an output terminal Pₒᵤₜ₁. The second switching unit 302 is electrically connected between a first level V_{DD} and the first terminal of the switch SW32, and has an input terminal Pᵢₙ₂ and an output terminal Pₒᵤₜ₂. The second terminal of the switch SW32 is electrically connected to a fourth level V_{CL}. The first terminal of the switch SW33 is electrically connected to the third level AV_{DD}. The first terminal of the switch SW34 is electrically connected to the second terminal of the switch SW33, while the second terminal thereof is electrically connected to the fourth level V_{CL}. It can be seen from FIG. 3, a switching signal SL₁ is operated between the third level AV_{DD} and the second level V_{SS}, while a switching signal SL₂ is operated between the first level V_{DD} and the fourth level V_{CL}.

Continuing to FIG. 3, the operation principle of the embodiment can be referred in FIG. 3. The second unit 202 generates an output signal Sₒᵤₜ₂, which is immediately fed back to the first unit 201. The switches SW31 and SW32 in the first unit 201 are turned on or off according to the output signal Sₒᵤₜ₂. When an input signal Sᵢₙ₂ takes a high-voltage level (for example, the first level V_{DD}), the first switching unit 301 would at the output terminal Pout1 output the switching signal SL₁ with a low-voltage level (for example, the second level V_{SS}) to the second unit 202 according to the input signal Sᵢₙ₂ and the on status of the first switch SW31; at the point, the second switching unit 302 would at the output terminal Pout2 output the switching signal SL₂ with a low-voltage level (for example, the fourth level V_{CL}) to the second unit 202 according to the input signal Sᵢₙ₂ and the on status of the second switch SW32. The second unit 202 controls the switch SW33 and the switch SW34 according to the switching signal SL₁ and the switching signal SL₁ (at the point, the switch SW33 is turned on, while the switch SW34 is turned off) and generates the output signal Sₒᵤₜ₂ with a higher voltage level (for example, the third level AV_{DD}). The output signal Sₒᵤₜ₂ is immediately fed back to the first unit 201, which keeps the switch SW31 in off status and the switch SW32 in on status.

On the other hand, when the input signal Sᵢₙ₂ takes a low-voltage level (for example, the second level V_{SS}), the second switching unit 302 would at the output terminal Pout2 output the switching signal SL₂ with a high-voltage level (for example, the first level V_{DD}) to the second unit 202 according to the input signal Sᵢₙ₂ and the on status of the second switch SW32; at the point, the first switching unit 301 would at the output terminal Pout1 output the switching signal SL₁ with a high-voltage level (for example, the third level AV_{DD}) to the second unit 202 according to the input signal Sᵢₙ₂ and the on status of the first switch SW32. The second unit 202 turns on the switch SW34 and turns off the switch SW33 according to the switching signal SL₁ and the switching signal SL₁, and the output signal Sₒᵤₜ₂ herein takes a lower voltage level (for example, the fourth level V_{CL}). The output signal Sₒᵤₜ₂ is immediately fed back to the first unit 201, which keeps the switch SW32 in off status and the switch SW31 in on status. In short, the level-shifting apparatus of the present invention is able to change the input signal Sᵢₙ₂ operated between the first level V_{DD} and the second level V_{SS} to the output signal Sₒᵤₜ₂ operated between the third level AV_{DD} and the fourth level V_{CL}.

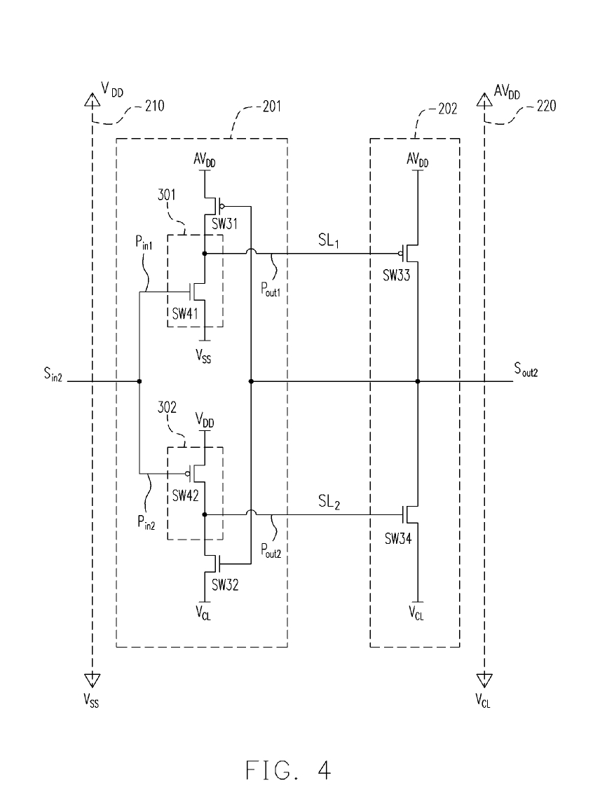

Further continuing to FIG. 4, it is a circuit drawing of the first switching unit 301 and the second switching unit 302 in FIG. 3, where the detailed configuration of the embodiment is illustrated. As shown in FIG. 4, the first switching unit 301 is formed by a switch SW41, while the second switching unit 302 is formed by a switch SW42. The switches SW41 and SW42 are respectively formed by an N-type transistor and a P-type transistor. The first terminal of the switch SW41 is electrically connected to the second terminal of the switch SW31 and the output terminal Pout1 of the switching unit 301, while the second terminal of the switch SW41 is electrically connected to the second level V_{SS}; the first terminal of the switch SW42 is electrically connected to the first level V_{DD}, while the second terminal of the switch SW42 is electrically connected to the first terminal of the switch SW32 and the output terminal Pout2 of the switching unit 302.

When the input signal Sᵢₙ₂ takes the first level V_{DD}, the first switching unit 301 would be turned on by the switch SW41 and at the output terminal Pout1 the switching signal SL₁ with the second level V_{SS} is output to the second unit 202. At the point, the switch SW42 of the second switching unit 302 keeps in off status according to the input signal Sᵢₙ₂, while the second unit 202 turns on the switch SW33 by means of the control of the switching signal SL₁, which accordingly advances the level of the output signal Sₒᵤₜ₂. The output signal Sₒᵤₜ₂ is fed back to the first unit 201, which turns the switch SW31 off and the switch SW32 on and further enables the first unit 201 to generate the switching signal SL₂ with the fourth level V_{CL} sent to the second unit 202. On the contrary, when the input signal Sᵢₙ₂ takes the second level V_{SS}, the switch SW41 is off. At the point, the switch SW42 is on, the first switching unit 301 temporarily does not output any signal and the second switching unit 302 outputs the switching signal SL₂ with the first level V_{DD}. After that, the output signal Sₒᵤₜ₂ fed back to the first unit 201 would turn on the switch SW31, which further enables the first switching unit 301 to generate the switching signal SL₁ with the third level AV_{DD}.

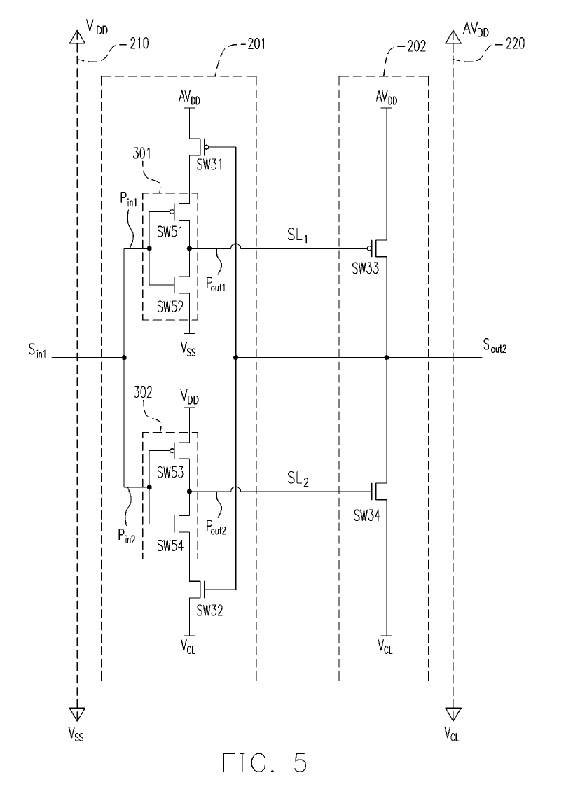

Another embodiment of the first switching unit 301 and the second switching unit 302 is described as follows. Similarly to the embodiment in FIG. 4, FIG. 5 is a circuit drawing of another embodiment of the present invention. As shown in FIG. 5, the first switching unit 301 is formed by a switch SW51 and a switch SW52, while the second switching unit 302 is formed by a switch SW53 and a switch SW54. The switches SW51 and SW53 are respectively formed by a P-type transistor, while the switches SW51 and SW53 are respectively formed by an N-type transistor. The first terminal of the switch SW51 is electrically connected to the second terminal of the switch SW31 and the second terminal of the switch SW51 is electrically connected to the output terminal Pout1; the first terminal of the switch SW52 is electrically connected to the second terminal of the switch SW51 and the second terminal of the switch SW52 is electrically connected to the second level V_{SS}; the first terminal of the switch SW53 is electrically connected to the first level V_{DD} and the second terminal of the switch SW53 is electrically connected to the output terminal Pout2; the first terminal of the switch SW54 is electrically connected to the second terminal of the switch SW53 and the second terminal of the switch SW54 is electrically connected to the first terminal of the switch SW32.

When the input signal Sᵢₙ₂ takes the first level V_{DD}, the switches SW52 and SW54 are on, the switches SW51 and SW53 are off, the level of the output terminal is pulled to the second level V_{SS}, and the output terminal Pout2 takes floating status and does not output any signal. Once the output signal Sₒᵤₜ₂ fed back to the first unit 201 enables the switch SW32 to be turned on, the level of the output terminal Pout2 is pulled to the fourth level V_{CL}. When the input signal takes the second level V_{SS}, the switches SW51 and SW53 are on, the switches SW52 and SW54 are off, the level of the output terminal Pout2 is pulled to the first level V_{DD}, and the output terminal Pout1 takes floating status and does not output any signal. After that, the output signal Sₒᵤₜ₂ fed back to the first unit 201 would turn on the switch SW31, which further enables the first switching unit 301 to generate the switching signal SL₁ with the third level AV_{DD}.

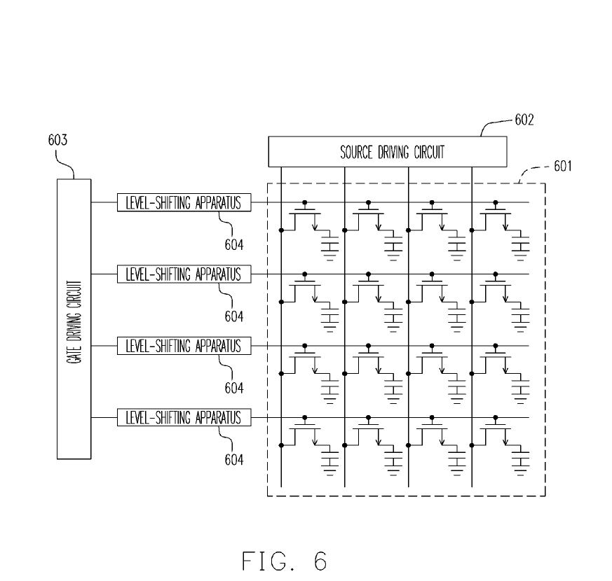

FIG. 6 illustrates an embodiment of a panel display apparatus according to the present invention. Referring to FIG. 6, the panel display apparatus includes a display panel 601, a source driving circuit 602, a gate driving circuit 603 and a level-shifting apparatus 604. The source driving circuit 602 is electrically connected to the display panel 601. The level-shifting apparatus 604 is connected in series between the display panel 601 and the gate driving circuit 603. The source driving circuit 602 is used for outputting a source signal needed by the display panel 601. The gate driving circuit 603 sequentially outputs a first gate signal for switching pixels according to the timing of the source driving circuit 602. Cooperating with the voltage level of the source signal, the level of the first gate signal prior to being sent to the display panel 601 must be adjusted by the level-shifting apparatus 604, so as to generate a second gate signal capable of normally switching pixels. Wherein, the first gate signal is operated between the first level and the second level, while the second gate signal is operated between the third level and the fourth level.

In the above-described panel display apparatus, the level-shifting apparatus 604 thereof is basically the same as the embodiment in FIG. 2, i.e., it is formed by a first unit and a second unit. Besides, the first unit decides whether the switching signal and the switching signal are to be output according to the first gate signal and the second gate signal, while the second unit generates the second gate signal according to the first switching signal and the second switching signal. Wherein, the first switching signal is operated between the third level and the second level, while the second switching signal is operated between the first level and the fourth level. The level-shifting apparatus 604 can be further implemented referring to FIG. 4 or FIG. 5. Since the similar description is given in the above-described embodiment, the detail of the level-shifting apparatus 604 is omitted to describe for simplicity.

In summary, a conventional level-shifting apparatus requires two stages of level shifters to change the level of an input signal in separated divisions. That is to say, first, the first stage of level shifters is used to shift the high-voltage level of the input signal to a higher level, and then the second stage of level shifters is used to shift the low-voltage level of the input signal to a lower level. In comparison with the prior art, the present invention uses a single-stage level-shifting apparatus to simultaneously convert both the high-voltage level and the low-voltage level of the input signal into a higher level and a lower level, respectively. Therefore, a less transistor number is needed to achieve the original function of changing signal levels. For an application employing the level-shifting apparatus of the present invention to a large scale (for example, the driving circuit of a display panel), the present invention can effectively reduce the circuit layout area and save the production cost.

It will be apparent to those skilled in the art that various modifications and variations can be made to the structure of the present invention without departing from the scope or spirit of the invention. In view of the foregoing, it is intended that the specification and examples to be considered as exemplary only, with a true scope and spirit of the invention being indicated by the following claims and their equivalents.

What is claimed is:

1. A level-shifting apparatus, used for receiving and changing the level of an input signal to generate an output signal; the apparatus comprising:
a first unit, used for deciding whether a first switching signal and a second switching signal are to be output according to the input signal and the output signal, wherein the input signal is operated between a first level and a second level, the first switching signal is operated between a third level and the second level, and the second switching signal is operated between the first level and a fourth level; and
a second unit, electrically connected to the first unit and used for generating the output signal according to the first switching signal and the second switching signal, wherein the output signal is operated between the third level and the fourth level.

2. The level-shifting apparatus as recited in claim 1, wherein the level relationships among the first level, the second level, the third level and the fourth level are: the third level>the first level>the second level>the fourth level.

3. The level-shifting apparatus as recited in claim 1, wherein the first unit comprises:
a first switch, wherein the first terminal thereof is electrically connected to the third level for deciding the on/off status between the first terminal and the second terminal thereof according to the output signal;
a first switching unit, electrically connected between the second terminal of the first switch and the second level, having a first input terminal for receiving the input signal and a first output terminal for outputting the first switching signal, and used for determining the level of the first switching signal according to the input signal and the on/off status of the first switch;
a second switch, wherein the second terminal thereof is electrically connected to the fourth level for deciding the on/off status between the first terminal and the second terminal thereof according to the output signal; and
a second switching unit, electrically connected between the first level and the first terminal of the second switch, having a second input terminal electrically connected to the first input terminal and a second output terminal for outputting the second switching signal, and used for determining the level of the second switching signal according to the input signal and the on/off status of the second switch.

4. The level-shifting apparatus as recited in claim 3, wherein the first switch comprises a P-type transistor, while the second switch comprises an N-type transistor.

5. The level-shifting apparatus as recited in claim 3, wherein the first switching unit comprises:
a third switch, wherein the first terminal thereof is electrically connected to the second terminal of the first switch and the first output terminal, the second terminal of the third switch is electrically connected to the second level for deciding the on/off status between the first terminal and the second terminal thereof according to the input signal received by the first input terminal.

6. The level-shifting apparatus as recited in claim 5, wherein the third switch comprises an N-type transistor.

7. The level-shifting apparatus as recited in claim 3, wherein the second switching unit comprises:
a fourth switch, wherein the first terminal thereof is electrically connected to the first level and the second terminal thereof is electrically connected to the first terminal of the second switch and the second output terminal for deciding the on/off status between the first terminal and the second terminal thereof according to the input signal received by the second input terminal.

8. The level-shifting apparatus as recited in claim 7, wherein the fourth switch comprises a P-type transistor.

9. The level-shifting apparatus as recited in claim 3, wherein the first switching unit comprises:
a fifth switch, wherein the first terminal thereof is electrically connected to the second terminal of the first switch and the second terminal thereof is electrically connected to the first output terminal for deciding the on/off status between the first terminal and the second terminal thereof according to the input signal received by the first input terminal; and
a sixth switch, wherein the first terminal thereof is electrically connected to the second terminal of the fifth switch and the second terminal thereof is electrically connected to the second level for deciding the on/off status between the first terminal and the second terminal thereof according to the input signal received by the first input terminal.

10. The level-shifting apparatus as recited in claim 9, wherein the fifth switch comprises a P-type transistor, while the sixth switch comprises an N-type transistor.

11. The level-shifting apparatus as recited in claim 3, wherein the second switching unit comprises:
a seventh switch, wherein the first terminal thereof is electrically connected to the first level and the second terminal thereof is electrically connected to the second output terminal for deciding the on/off status between the first terminal and the second terminal thereof according to the input signal received by the second input terminal; and
an eighth switch, wherein the first terminal thereof is electrically connected to the second terminal of the seventh switch and the second terminal thereof is electrically connected to the first terminal of the second switch for deciding the on/off status between the first terminal and the second terminal thereof according to the input signal received by the second input terminal.

12. The level-shifting apparatus as recited in claim 11, wherein the seventh switch comprises a P-type transistor, while the eighth switch comprises an N-type transistor.

13. The level-shifting apparatus as recited in claim 1, wherein the second unit comprises:
a ninth switch, wherein the first terminal thereof is electrically connected to the third level and the second terminal thereof is used for outputting the output signal and the ninth switch decides the on/off status between the first terminal and the second terminal thereof according to the first switching signal; and
a tenth switch, wherein the first terminal thereof is electrically connected to the second terminal of the ninth switch, the second terminal thereof is electrically connected to the fourth level and the tenth switch decides the on/off status between the first terminal and the second terminal thereof according to the second switching signal.

14. A panel display apparatus, at least comprising:
a display panel;
a source driving circuit, electrically connected to the display panel and used for outputting a source signal to drive the display panel;
a gate driving circuit, used for outputting a first gate signal cooperating with the timing of the source driving circuit, wherein the first gate signal is operated between a first level and a second level; and
a level-shifting apparatus, electrically connected in series between the display panel and the gate driving circuit and used for receiving and changing the level of the first gate signal to generate a second gate signal, wherein the second gate signal is operated between a third level and a fourth level and the level-shifting apparatus comprises:
a first unit, used for deciding whether a first switching signal and a second switching signal are to be output according to the first gate signal and the second gate signal, wherein the first switching signal is operated between the third level and the second level, while the second switching signal is operated between the first level and the fourth level; and
a second unit, electrically connected to the first unit and used for generating the second gate signal according to the first switching signal and the second switching signal.

15. The panel display apparatus as recited in claim 14, wherein the level relationships among the first level, the second level, the third level and the fourth level are: the third level>the first level>the second level>the fourth level.

16. The panel display apparatus as recited in claim 14, wherein the first unit comprises:
a first switch, wherein the first terminal thereof is electrically connected to the third level for deciding the on/off status between the first terminal and the second terminal thereof according to the second gate signal;
a first switching unit, electrically connected between the second terminal of the first switch and the second level, having a first input terminal for receiving the first gate signal and a first output terminal for outputting the first switching signal, and used for deciding whether the first switching signal is to be output according to the first gate signal and the on/off status of the first switch;
a second switch, wherein the second terminal thereof is electrically connected to the fourth level for deciding the on/off status between the first terminal and the second terminal thereof according to the second gate signal; and
a second switching unit, electrically connected between the first level and the first terminal of the second switch, having a second input terminal electrically connected to the first input terminal and a second output terminal for outputting the second switching signal, and used for deciding whether the second switching signal is to be output according to the first gate signal and the on/off status of the second switch.

17. The panel display apparatus as recited in claim 16, wherein the first switch comprises a P-type transistor, while the second switch comprises an N-type transistor.

18. The panel display apparatus as recited in claim 16, wherein the first switching unit comprises:
a third switch, wherein the first terminal thereof is electrically connected to the second terminal of the first switch and the first output terminal, the second terminal of the third switch is electrically connected to the second level for deciding the on/off status between the first terminal and the second terminal thereof according to the first gate signal received by the first input terminal.

19. The panel display apparatus as recited in claim 18, wherein the third switch comprises an N-type transistor.

20. The panel display apparatus as recited in claim 16, wherein the second switching unit comprises:
a fourth switch, wherein the first terminal thereof is electrically connected to the first level and the second terminal thereof is electrically connected to the first terminal of the second switch and the second output terminal for deciding the on/off status between the first terminal and the second terminal thereof according to the first gate signal received by the second input terminal.

21. The panel display apparatus as recited in claim 20, wherein the fourth switch comprises a P-type transistor.

22. The panel display apparatus as recited in claim 16, wherein the first switching unit comprises:
a fifth switch, wherein the first terminal thereof is electrically connected to the second terminal of the first switch and the second terminal thereof is electrically connected to the first output terminal for deciding the on/off status between the first terminal and the second terminal thereof according to the first gate signal received by the first input terminal; and
a sixth switch, wherein the first terminal thereof is electrically connected to the second terminal of the fifth switch and the second terminal thereof is electrically connected to the second level for deciding the on/off status between the first terminal and the second terminal thereof according to the first gate signal received by the first input terminal.

23. The panel display apparatus as recited in claim 22, wherein the fifth switch comprises a P-type transistor, while the sixth switch comprises an N-type transistor.

24. The panel display apparatus as recited in claim 16, wherein the second switching unit comprises:
a seventh switch, wherein the first terminal thereof is electrically connected to the first level and the second terminal thereof is electrically connected to the second output terminal for deciding the on/off status between the first terminal and the second terminal thereof according to the first gate signal received by the second input terminal; and
an eighth switch, wherein the first terminal thereof is electrically connected to the second terminal of the seventh switch and the second terminal thereof is electrically connected to the first terminal of the second switch for deciding the on/off status between the first terminal and the second terminal thereof according to the first gate signal received by the second input terminal.

25. The panel display apparatus as recited in claim 24, wherein the seventh switch comprises a P-type transistor, while the eighth switch comprises an N-type transistor.

26. The panel display apparatus as recited in claim 14, wherein the second unit comprises:
a ninth switch, wherein the first terminal thereof is electrically connected to the third level, the second terminal thereof is used for outputting the second gate signal and the ninth switch decides the on/off status between the first terminal and the second terminal thereof according to the first switching signal; and
a tenth switch, wherein the first terminal thereof is electrically connected to the second terminal of the ninth switch, the second terminal thereof is electrically connected to the fourth level and the tenth switch decides the on/off status between the first terminal and the second terminal thereof according to the second switching signal.
